(19) United States
(12) Patent Application Publication
(10) Pub. No.: US 2004/0227578 A1
(43) Pub. Date: Nov. 18, 2004

(54) Acoustic resonance-based frequency synthesizer using at least one bulk acoustic wave (BAW) or thin film bulk acoustic wave (FBAR) device

(76) Inventor: Miikka Hamalainen, Espoo (FI)

Correspondence Address: HARRINGTON & SMITH, LLP, 4 RESEARCH DRIVE, SHELTON, CT, 06484-6212, US

(21) Appl. No.: 10/439,260

(22) Filed: May 14, 2003

(51) Int. Cl. H03B 5/32

(52) U.S. Cl. 331/107 A

(57) ABSTRACT

A frequency synthesizer is constructed to include a reference oscillator; a phase comparator having a first input coupled to an output of said reference oscillator and outputting a frequency tuning voltage; a VCO having an input coupled to the frequency tuning voltage and outputting an output frequency signal and a programmable divider coupled to the output frequency signal and providing a divided output frequency signal to a second input of the phase comparator. In the presently preferred embodiment the VCO includes at least one acoustic resonator coupled to the frequency tuning voltage. In another preferred embodiment a plurality of capacitances are switchably coupled in parallel with the at least one acoustic resonator for extending a tuning range of the VCO. Preferably at least the phase comparator, the VCO, including the at least one acoustic resonator and the switchable capacitances, and the programmable divider are all integrated on a single integrated circuit substrate. The frequency synthesizer may form a part of a wireless communication device, such as a cellular telephone. The reference oscillator can also include at least one acoustic resonator, such as one coupled to an automatic frequency control tuning voltage.

### TECHNICAL FIELD

This invention relates generally to radio frequency (RF) oscillators and, more specifically, relates to RF voltage controlled oscillators and frequency synthesizers for use in communications devices, including cellular radio transceivers and related equipment, such as mobile stations including cellular telephones.

### BACKGROUND

In cellular radio transceivers, channel selection is typically achieved with some form of frequency synthesis. In every radio transceiver, a local oscillator (LO) is required irrespective of the RF architecture. Typically the LO signal is used to mix the desired frequency down to an intermediate frequency (IF), or directly to baseband (i.e., zero Hertz or substantially zero Hertz) and vice verse (i.e., the LO can be used to up-convert a signal to IF or to the final transmit frequency.)

In LO generation there are basically two methods that can be used: direct digital synthesis (DDS) and indirect synthesis, or phased locked loop (PLL). Currently, however, the DDS approach is not practical for a battery powered mobile station mainly due to the relatively high power consumption. Consequently, and at least because of its reduced power requirements, the indirect synthesis or PLL approach is the most widely used LO generation method for mobile stations.

General reference with regard to local oscillators, and more specifically voltage controlled oscillators (VCOs) and also PLLs, can be made to the following commonly assigned U.S. patents: U.S. Pat. No. 5,079,520, “Interpolating Phase-Locked Loop Frequency Synthesizer”, by Juha Rapeli; U.S. Pat. No. 5,357,222, “Voltage Controlled Component Including a Capacitive Diode Biased to Operate in the Linear Region”, by Seppo Hietala; U.S. Pat. No. 5,565,821, “Voltage Controlled Oscillator with Improved Tuning Linearity”, by Simo Murtojarvi; U.S. Pat. No. 5,751,194, “Phase-Locked Loop Having Charge Pump Controlled According to Temperature and Frequency”, by Mika Haapanen and André Dekker; U.S. Pat. No. 5,764,109, “Voltage-Controlled Oscillator (VCO) Having a Voltage Derived from its Output to Tune its Center Frequency”, by Osmo Kukkonen; and U.S. Pat. No. 5,889,443, “Frequency Synthesizing Circuit Using a Phase-Locked Loop”, by Klaus Jørgensen. In general, a PLL phase detector generates a DC voltage that is used for VCO frequency tuning.

FIG. 1 is a block diagram of a conventional PLL structure of a frequency synthesizer 10. A master oscillator (VCTCXO) 12 outputs a master frequency to a frequency scaler (1/R) block 14 that then outputs a reference frequency f_{ref}. The reference frequency is applied to a charge pump phase-frequency detector (PFD) 16. The PFD 16 outputs an analog voltage signal to a loop filter 18, which then applies a filtered analog signal to the VCO 20. The filtered analog signal drives a component, such as a tuning or varactor diode, that is responsive to the analog signal for changing its fundamental output frequency. The output frequency fₒᵤₜ of the frequency synthesizer 10 is also fed-back to the input of the PFD 16, via a frequency divider (1/N) block 22, which results in locking the phase (and frequency) of fₒᵤₜ to f_{ref}, hence the term “phase-locked loop”.

While well suited for their intended applications, the use of the above-mentioned and other VCOs and PLLs will become more problematic as integrated circuit technologies continue to evolve, and as frequency control in modern and future mobile communications devices becomes more demanding. For the future implementation of frequency synthesis circuitry, especially considering future multi-mode RF platforms constructed using pure, fine-line CMOS processes with reduced supply voltage (e.g., one volt or even less), considerations of circuit area, power consumption, settling time and close-in phase-noise performance become more important.

It is known in the art that the resonant frequency of a bulk acoustic wave (BAW) resonator can be adjusted by connecting variable DC-voltage between the BAW electrodes. For example, in commonly assigned U.S. Pat. No. 5,714,917, “Device Incorporating a Tunable Thin Film Bulk Acoustic Resonator for Performing Amplitude and Phase Modulation”, by Juha Ellä, a discussion is made of a tunable Bulk Acoustic resonator, and reference is made to U.S. Pat. No. 5,446,306, Stokes et al., for disclosing a Thin Film Voltage-Tuned Semiconductor Bulk Acoustic Resonator (SBAR). This device includes a piezoelectric film positioned between a first and a second electrode. The second electrode is positioned adjacent to a substrate containing a via hole. In response to a variable voltage source applying a DC bias voltage to the electrodes, an electric field is created between the electrodes within the piezoelectric film. As a result, the piezoelectric film vibrates at a frequency that is different than its unbiased resonant frequency. The resonant frequency of the SBAR can be varied by adjusting the DC bias voltage.

Other commonly assigned patents of interest in this area include: U.S. Pat. No. 5,872,493, “Bulk Acoustic Wave (BAW) Filter Having a Top Portion that Includes a Protective Acoustic Mirror”, Juha Ellä; U.S. Pat. No. 6,204,737 B1, “Piezoelectric Resonator Structures with a Bending Element Performing a Voltage Controlled Switching Function”, Juha Ellä; and U.S. Pat. No. 6,242,843 B1, “Resonator Structures”, Helena Pohjonen and Juha Ellä.

For example, and referring to U.S. Pat. No. 6,242,843, col. 8, lines 25-42, FIG. 14 is said to show an oscillator circuit of the well-known Colpitts type. A bulk acoustic wave resonator and switch bank 302 that comprises micromechanical switches 320 and bulk acoustic wave resonators 300 is used for providing several operation frequencies for the oscillator circuit. The desired operating frequency is selected by selecting the corresponding resonator with one of the switches 320. This kind of an oscillator structure can advantageously be used, for example, in a multi-band mobile communication device.

One potential problem that can arise with the use of a BAW resonator in an oscillator circuit, in particular a frequency synthesizer circuit, is the resulting narrow tuning range of one single BAW resonator. In fact, the tuning range of a single BAW resonator would not be sufficient for use in cellular systems or in, for example, a Bluetooth frequency synthesizer.

### SUMMARY OF THE PREFERRED EMBODIMENTS

The foregoing and other problems are overcome, and other advantages are realized, in accordance with the presently preferred embodiments of these teachings.

The invention provides embodiments of circuitry to implement a frequency synthesis function using an acoustic resonator, such as a bulk acoustic wave (BAW) resonator or a thin film bulk acoustic resonator (FBAR). In this invention the conventional VCO circuitry is replaced with at least one tunable and controllable BAW resonator in a PLL system. The use of this invention enables a cost and die-area efficient implementation of a frequency synthesizer. Furthermore, the frequency synthesizer settling time and close-in phase-noise performance are improved relative to current frequency synthesizer circuits, and the current consumption can be reduced by an order of magnitude. This use of this invention is especially advantageous when implementing a frequency synthesizer using nano-scale digital CMOS processes.

This invention provides a VCO circuit for a PLL frequency synthesizer, suitable for use in a mobile communications terminal or mobile station. The VCO circuit contains at least one BAW resonator structure. The PLL phase detector generates a DC voltage for use in VCO frequency tuning. In accordance with this invention, the voltage is coupled to a BAW electrode to tune the BAW resonant frequency so as to lock the frequency synthesizer output frequency to a reference frequency.

In accordance with an aspect of this invention there is provided a tuning network, such as one constructed from a switched capacitance network, that is coupled in parallel with the BAW resonator, and that can be used to change the effective parallel capacitance of the BAW resonator, thereby varying the resonant frequency of the BAW resonator. A two-level frequency control may thus be provided, with the switched capacitance network providing a gross tuning function, and the DC voltage applied to the BAW resonator providing a fine tuning function. In the same or another embodiment a plurality of BAW resonators, each with a different characteristic resonant center frequency, can be provided with a switching network for further enhancing the tunability of the BAW-based frequency synthesizer.

In accordance with this invention a frequency synthesizer is constructed to include a reference oscillator; a phase comparator having a first input coupled to an output of the reference oscillator and outputting a frequency tuning voltage; a VCO having an input coupled to the frequency tuning voltage and outputting an output frequency signal and a programmable divider coupled to the output frequency signal and providing a divided output frequency signal to a second input of the phase comparator. In the presently preferred embodiment the VCO includes at least one acoustic resonator coupled to the frequency tuning voltage. In another preferred embodiment a plurality of capacitances are switchably coupled in parallel with the at least one acoustic resonator for extending a tuning range of the VCO. Preferably at least the phase comparator, the VCO, including the at least one acoustic resonator and the switchable capacitances, and the programmable divider are all integrated on a single integrated circuit substrate. The frequency synthesizer may form a part of a wireless communication device, such as a cellular telephone.

In a further embodiment the reference oscillator can include at least one acoustic resonator, such as one coupled to an automatic frequency control tuning voltage.

### BRIEF DESCRIPTION OF THE DRAWINGS

The foregoing and other aspects of these teachings are made more evident in the following Detailed Description of the Preferred Embodiments, when read in conjunction with the attached Drawing Figures, wherein:

FIG. 1 is a block diagram of a conventional PLL structure of a frequency synthesizer;

FIG. 2 is a block diagram that shows an embodiment of an acoustic resonance-based frequency synthesizer having a capacitor array for controlling the BAW resonator frequency;

FIG. 3 shows a block diagram of a further embodiment of a frequency synthesizer that includes a plurality of BAW components and a tuning capacitance matrix for extending the tuning range of the synthesizer;

FIG. 4 shows a block diagram of a mobile station that includes the frequency synthesizer of FIG. 3;

FIG. 5 illustrates a BAW resonator tuning method; and

FIG. 6 is a block diagram that shows a further embodiment of this invention wherein the reference frequency oscillator of FIG. 3 is also implemented using a BAW resonator.

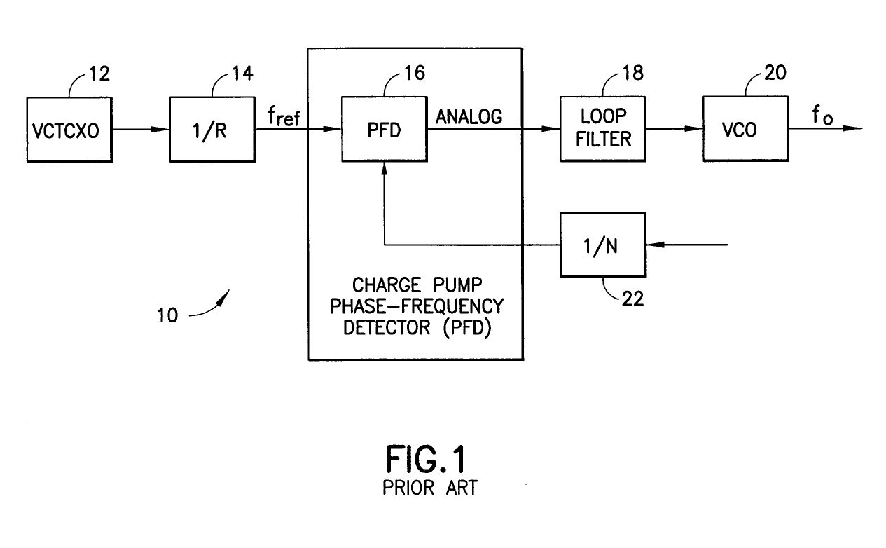

### DETAILED DESCRIPTION OF THE PREFERRED EMBODIMENTS

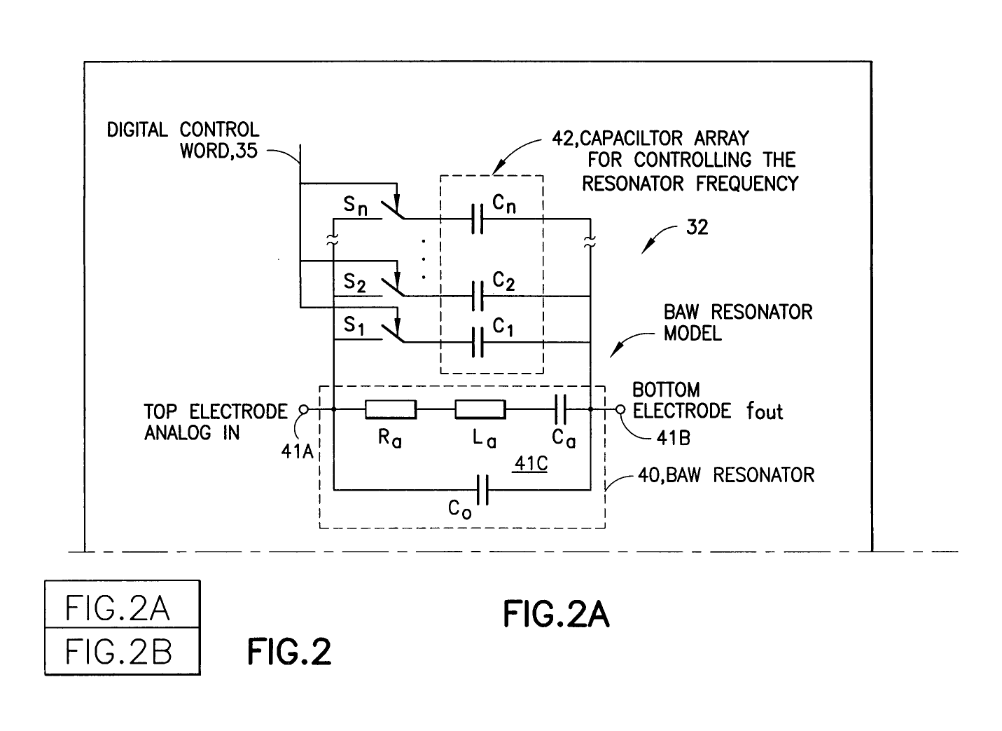

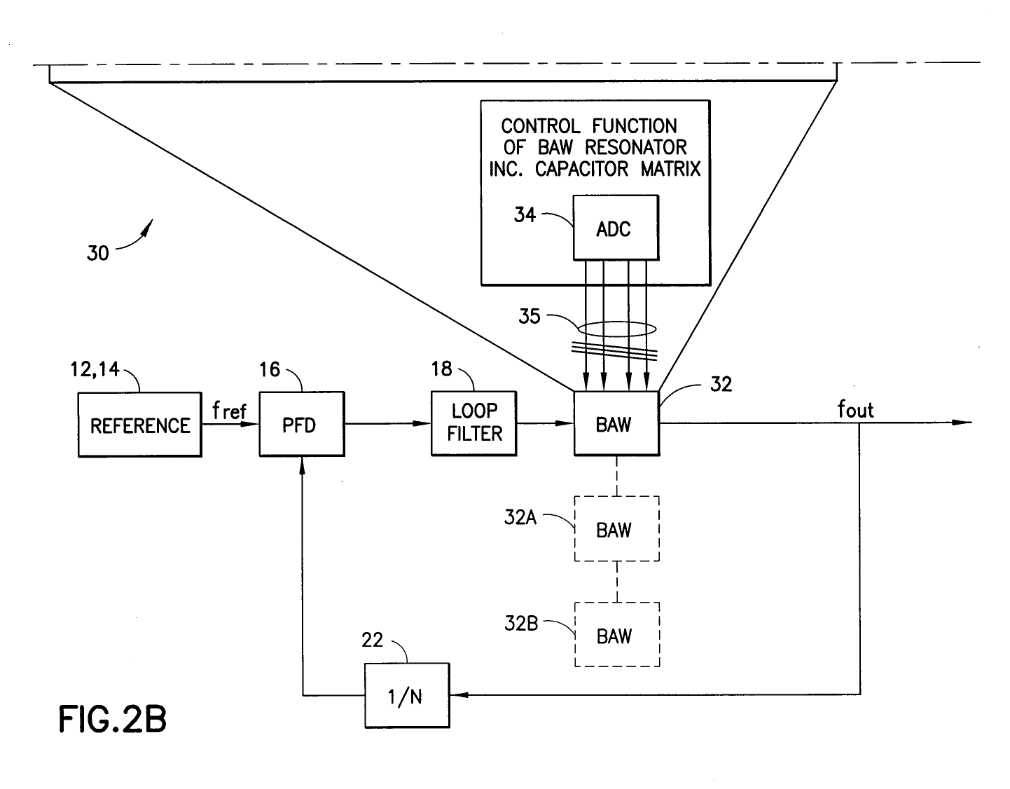

FIG. 2 is a block diagram that shows a presently preferred embodiment of an acoustic resonance-based frequency synthesizer 30. The frequency synthesizer 30 includes a capacitor matrix or array 42 for controlling a BAW component 32 resonant frequency. The BAW component 32 is shown to include a BAW device 40 modeled as a top (input) electrode 41A for receiving the analog signal from the PFD 16 via the loop filter 18. The BAW resonator device 40 further includes a bottom (output) electrode 41B for outputting fₒᵤₜ. Interposed between the top electrode 40A and the bottom electrode 41B is a layer 41C of piezoelectric material. The equivalent BAW circuit includes a series connected resistance Rₐ, inductance Lₐ and capacitance Cₐ, in addition to a parallel capacitance Cₒ. There may be one or more additional BAW components (e.g., 32A, 32B) used for extending the tuning range of the frequency synthesizer 30.

The capacitor array 42 includes a plurality of capacitances C₁, C₂, . . . , Cₙ, typically having different values. The capacitor array 42 is connected in parallel with Cₒ, and a digital control word 35 controls the open/closed states of solid-state switches S₁, S₂, . . . , Sₙ, for placing one or more of the capacitance C₁, C₂, . . . , Cₙ in parallel with Cₒ. By placing one or more of the capacitance C₁, C₂, . . . , Cₙ in parallel with Cₒ the resonant frequency of the BAW 40 is changed, which the desired result to increase the tuning range. The frequency output around the resonant frequency may then be tuned with the analog input signal applied to the BAW resonator 40 top electrode 40A. The use of multiple BAW resonators 32A, 32B, each having a different resonant frequency, in cooperation with the capacitor array 42, even further extends the tuning range of the synthesizer 30, as will be described in further detail below.

Note in FIG. 2 that a multi-bit analog-to-digital converter (ADC) 34 may be employed to generate the digital control word 35, thereby enabling analog control over the value of fₒᵤₜ. In other embodiments the digital control word 35 can be provided from a conventional digital bus, under the control of a mobile station data processor (not shown in FIG. 2).

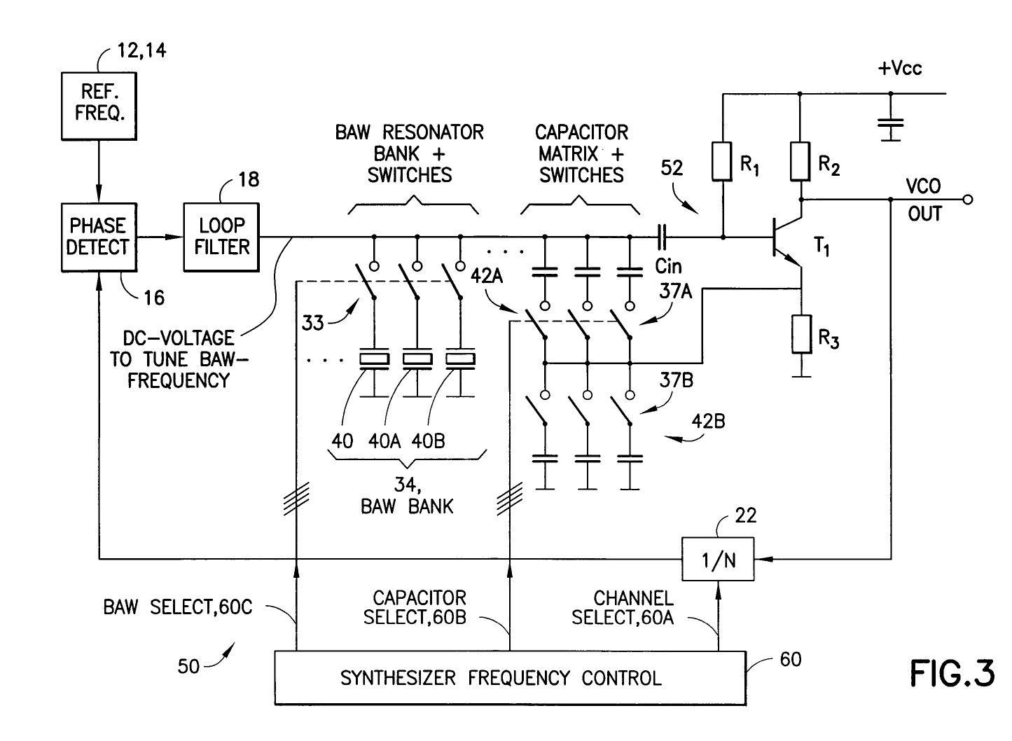

FIG. 3 shows a block diagram of a further embodiment of a frequency synthesizer 50 that includes an oscillator circuit 52 comprised of transistor T1 and resistances R1, R2 and R3, and input capacitance Cᵢₙ. The oscillation frequency of the oscillator 52 is a function of the capacitance networks 42A, 42B connected, via switch array 37A, from the base of T1 to ground, and connected, via switch array 37B, to the emitter of T1. A plurality of BAW resonators 40, 40A and 40B of a BAW bank 34 are switchably coupled in parallel with the selected capacitances of capacitance networks 42A, 42B by an array of switches 33. A synthesizer frequency control circuit 60, which could be embodied as a mobile station digital signal processor (DSP) or another processor, or as dedicated logic, has outputs for controlling the divider 22 for selecting a frequency channel in a conventional manner, as well as outputs for controlling the capacitance networks 42A, 42B and outputs for controlling the selection of one or more BAW resonators 40, 40A, 40B of the bank 34 of BAW resonators. Thus, the synthesizer frequency control circuit 60 is shown outputting a channel select line 60A, a capacitor selection line 60B and a BAW select line 60C, as is described in further detail below with relation to FIG. 5. The analog voltage output from the loop filter 18 controls the frequency output of the selected one or more BAW resonators 40, 40A and 40B.

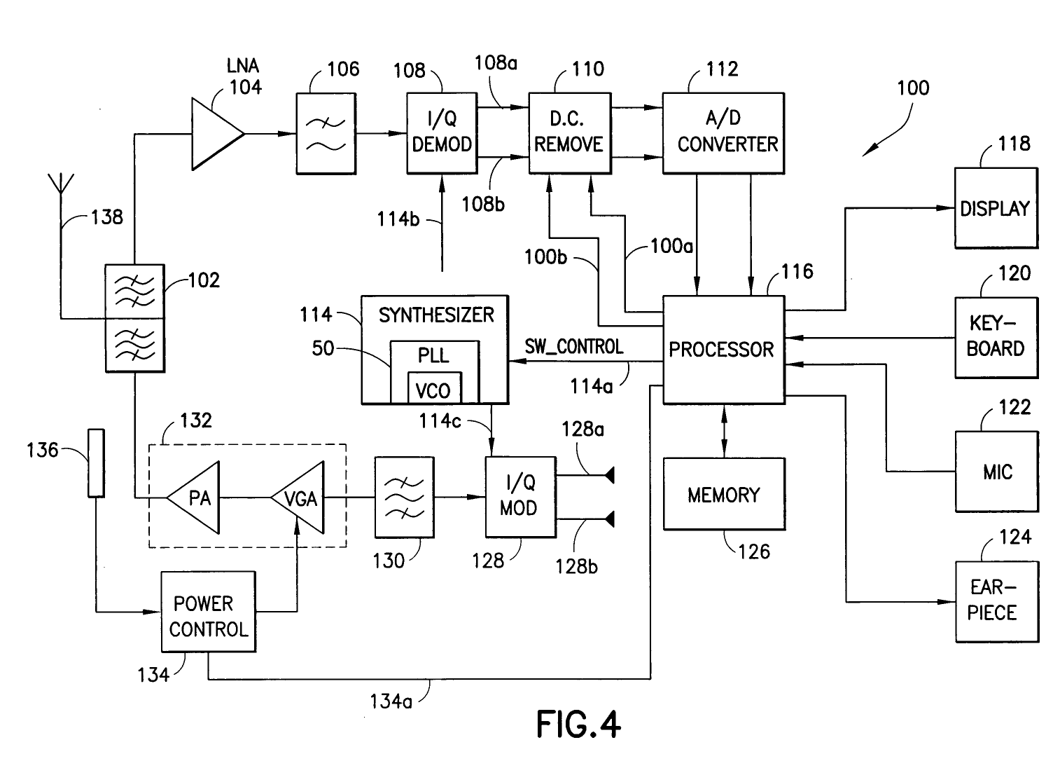

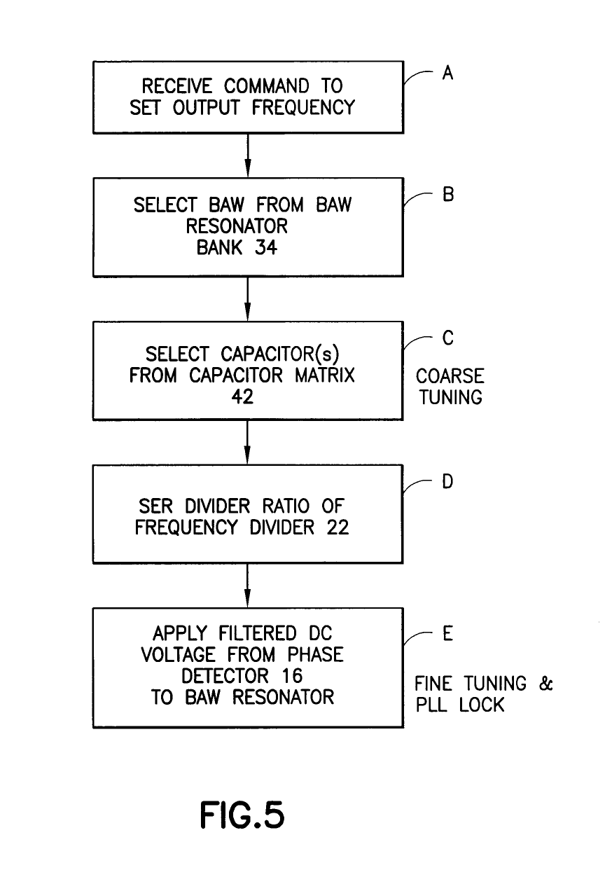

Reference is made now to FIG. 4 for showing the frequency synthesizer or VCO/PLL 50 in the context of a wireless communication device transceiver, such as a cellular telephone, also referred to herein for simplicity as a mobile station 100. The VCO/PLL 50 is assumed to include the circuitry shown in FIG. 3, including at least one BAW resonator 40 and the capacitance matrix or network(s) 42, and is further assumed to be integrated within an integrated circuit. More specifically, FIG. 4 is a block diagram of a transmitter-receiver (transceiver) of the mobile station 100, wherein the receiver is embodied, by example only, as a direct conversion receiver. An RF signal received by an antenna 138 is conducted via a duplex filter 102 to a low noise amplifier (LNA) 104. The purpose of the duplex filter 102 is to permit the use of the same antenna both in transmitting and in receiving. Instead of the duplex filter 102, a synchronous antenna changeover switch could be used in a time-division system. An RF signal output from the LNA 104 is low-pass filtered 106 and demodulated in an I/Q demodulator 108 into an in-phase (I) signal 108a and into a quadrature (Q) signal 108b. A local oscillator signal 114b, used for I/Q demodulation, is received from a frequency synthesizer 114. The frequency synthesizer 114 contains the VCOIPLL 50. In block 110, the removal of a DC voltage component is carried out, as is automatic gain control (AGC). Block 110 is controlled by a processing block 116 that may contain, for example, a microprocessor. Automatic gain control is regulated by a signal 110a and removal of the offset voltage is regulated by a signal 110b. The analog signals output from block 110 are converted into digital signals in block 112, and from which the digital signals are transferred to digital signal processing circuits in the processing block 116.

The transmitter portion of the mobile station 100 includes an I/Q modulator 128 that forms a carrier frequency signal from an in-phase (I) signal 128a and from a quadrature (Q) signal 128b. The I/Q modulator 128 receives a local oscillator signal 114c from the synthesizer 114. The generated carrier frequency signal is low-pass filtered and/or high-pass filtered by a filter 130 and is amplified by an RF amplifier 132 containing a variable gain amplifier (VGA) and a power amplifier (PA). The amplified RF signal is transferred via the duplex filter 102 to the antenna 138. A transmitter power control unit 134 controls the amplification of the RF amplifier 132 on the basis of the measured output power 136 and in accordance with a control signal 134a received from the processor 116.

The processor 116 also controls the synthesizer 114 using a programming line or bus 114a, whereby the output frequency of the synthesizer 114 is controllably changed, as when tuning to different transmission and reception channels and/or to different frequency bands. As such, the processor 116 can be embodied as the synthesizer frequency control block 60 of FIG. 3, or it can directly control the operation of the synthesizer control block 60 using programmed I/O over a digital data bus. In the preferred embodiment of this invention the programming bus 114A includes the various switch control SW_Control and other signals shown in FIG. 3, including the channel select line 60A, the capacitor selection line 60B and the BAW select line 60C, as described above. The processor 116 can include a digital signal processor DSP.

For completeness FIG. 4 also shows, connected to the processor 116, a memory unit 126 and a user interface having a display 118, a keyboard 120, a microphone 122 and an earpiece 124.

As is noted in U.S. Pat. No. 6,204,737 B1, it is known to construct thin film bulk acoustic resonators on semiconductor wafers, such as Si and GaAs wafers, as well as on glass substrates. The fabrication of the BAW resonators 40, 40A, 40B can be in accordance with any of the foregoing U.S. Pat. Nos. 5,714,917, 5,872,493, U.S. Pat. No. 6,204,737 B1 and U.S. Pat. No. 6,242,843 B1, which are incorporated by reference herein.

For example, each BAW resonator, such as the BAW resonator 40 of FIG. 2, can comprise the piezoelectric layer 41C, a plurality of protective layers, and the first and second electrodes 41A, 41B, where a portion of the piezoelectric layer 41C can be situated atop the electrode 41B, and where the electrode 41A is situated atop a portion of the piezoelectric layer 41C. In this manner, the electrodes 41A, 41B form a parallel plate structure between which the piezoelectric layer 41C is allowed to resonate or vibrate. The piezoelectric layer 41C may be comprised of any piezoelectric material that can be fabricated as a thin film such as, by example, zinc oxide, or aluminum nitride, and can have a thickness of, as one example, approximately 1.7 microns. The electrodes 41A and 41B may be comprised of any type of conductive material such as, by example, gold, and can have a thickness of, as one example, 0.1 microns. An isolating membrane (also referred to as a “bridge” or as a “supporting layer”) may comprise one or more layers, and can be comprised of, as examples, poly-silicon (poly-si), aluminum nitride, silicon dioxide, or gallium arsenide, depending on location. An air gap can be located under the BAW resonator 40, and formed within a portion of the underlying Si or GaAs substrate. The air gap functions to acoustically isolate vibrations produced by the piezoelectric layer 41C from the substrate.

In order to broaden the tuning range of the VCO/PLL 50 there may be several BAW resonators (e.g., 40, 40A, 40B) each having a different resonant frequency, for example: 905 MHz, 910 MHz, 915 MHz. The series resonant frequency Fₛ of a BAW resonatormay be defined as:

Fₛ=1/(2*π square root (Lₐ*Cₜₒₜ)), where:

Lₐ represents the equivalent circuit series inductance of the BAW resonator 40;

Cₜₒₜ represents the combined capacitance of the equivalent circuit series capacitor (Cₐ) of the BAW resonator component 32 and the selected capacitor (or capacitors) of the tuning capacitor array 42, (C₁ . . . Cₙ)=Cₜᵤₙₑ, yielding:

Cₜₒₜ=(Cₐ*Cₜᵤₙₑ)/(Cₐ+Cₜᵤₙₑ).

This formula shows that the BAW resonator frequency can be tuned downwards with the tuning capacitor matrix 42. As an example, the 905 MHz BAW resonator can be tuned down to about 900 MHz, the 910 MHz BAW resonator can be tuned down to about 905 MHz, and the 915 MHz BAW resonator can be tuned down to about 910 MHz. This forms a continuous tuning range from about 900 MHz to about 915 MHz. In practice, the resonant frequencies of BAW resonator(s) 40, 40A, 40B, and/or tuning capacitors 42, are selected so that the tunable BAWs overlap in frequency to some degree, to thereby avoid discontinuities in the frequency tuning range.

Referring to FIG. 5, an example of VCO/PLL 50 tuning procedure is as follows:

Step A. The synthesizer frequency control 60 receives a command to set to output frequency to 908 MHz.

Step B. The synthesizer frequency control 60 generates a BAW select signal 60C to select the 910 MHz BAW (e.g., BAW 40) from the BAW bank 34 via switch array 33.

Step C. The synthesizer frequency control 60 generates a capacitor select signal 60B to select, via switch arrays 37A and 37B, one or more capacitors from the capacitor matrix 42A, 42B to shift the 910 MHz BAW resonator frequency down to about 908 MHz, thereby coarsely tuning the PLL.

Step D. The synthesizer frequency control 60 generates a channel select signal 60A. This sets the divider 22 to a division ratio that corresponds to the desired PLL output frequency.

Step E. The phase detector 16 generates a DC voltage component proportional to the reference frequency 12,14 that is filtered by loop filter 18 and applied to the selected BAW resonator. The filtered DC voltage fine tunes the PLL frequency to 908 MHZ, and the PLL locks to the desired frequency.

In the preferred embodiment the capacitor matrix or array 42 is a binary array, i.e., an array wherein the capacitor values have the ratio 2, 4, 8, 16, 32 and so forth.

The fine tuning range depends on the BAW resonator properties and on the DC voltage tuning range. The fine tuning range may be extended by the use of a voltage converter that extends the tuning voltage range between the phase detector 16 and the selected BAW resonator 40, 40A, 40B.

In a multi-mode mobile station 100 separate BAW banks 34 can be used for tuning each mode (range of operating frequencies) separately.

The BAW resonators 40, 40A, 40B that are optimized for VCO/PLL 50 use may have their tuning range broadened by the use of external capacitors (or other external components).

It should further be noted that in FIG. 3 the BAW resonators 40, 40A, 40B of the BAW bank 34 have been depicted as physically separate components, however the BAW resonators may share one or more common resonator layers, such as the top electrode 40A, bottom electrode 40B and the intervening piezoelectric material layer. Thus, the act of selecting a BAW resonator using the switches 33 in FIG. 4 can actually be used for selecting a resonating portion of the BAW component.

By the use of the BAW resonator(s) 34 the LO portion of the frequency synthesizer circuitry can be fabricated in a die area that is significantly less (e.g., three to four times less) than a conventional VCO, depending on the required carrier frequency, or frequencies for a multi-band application. In addition, the resonator Q value (typically in the range of about 500 to 2000) is significantly higher than in traditional integrated VCOs, thereby achieving significantly improved close-in phase noise performance. Furthermore, the power consumption of the BAW resonator-based LO can be an order of magnitude lower (e.g., 1 mA) than the conventional VCO-based LO. Still further, the LO implementation using the BAW resonator facilitates the use of fine-line CMOS processes that use low supply voltages in RF circuitry, and also enables much faster frequency synthesizer settling times (<<100 microseconds) than currently available, thereby enabling the use of higher frequency RF bands, such as the 2.5 GHz band.

The use of this invention thus finds utility in current and future RF platforms. In particular, in future RF platforms the cellular radio is expected to be primarily digital, and will be implemented in a common silicon platform (i.e., digital CMOS) with the baseband (BB) functions. The use of this invention further enables high order modulation methods due to the enhanced close-in phase noise performance, and the fast settling times support advanced channel monitoring schemes in higher frequency bands.

A significant aspect of this invention is the ability to integrate the BAW resonator(s) 40, 40A, 40B on the same substrate (e.g., Si or GaAs) used for the PLL circuit. In addition, the switches 33 for BAW resonator selection can realized on same substrate, as can the capacitance network(s) 42 and the associated switches. The various switches may be, for example, FET transistors or MEMS switches. Thus, the use of this embodiment of the invention enables a fully integrated frequency synthesizer to be realized on a single substrate.

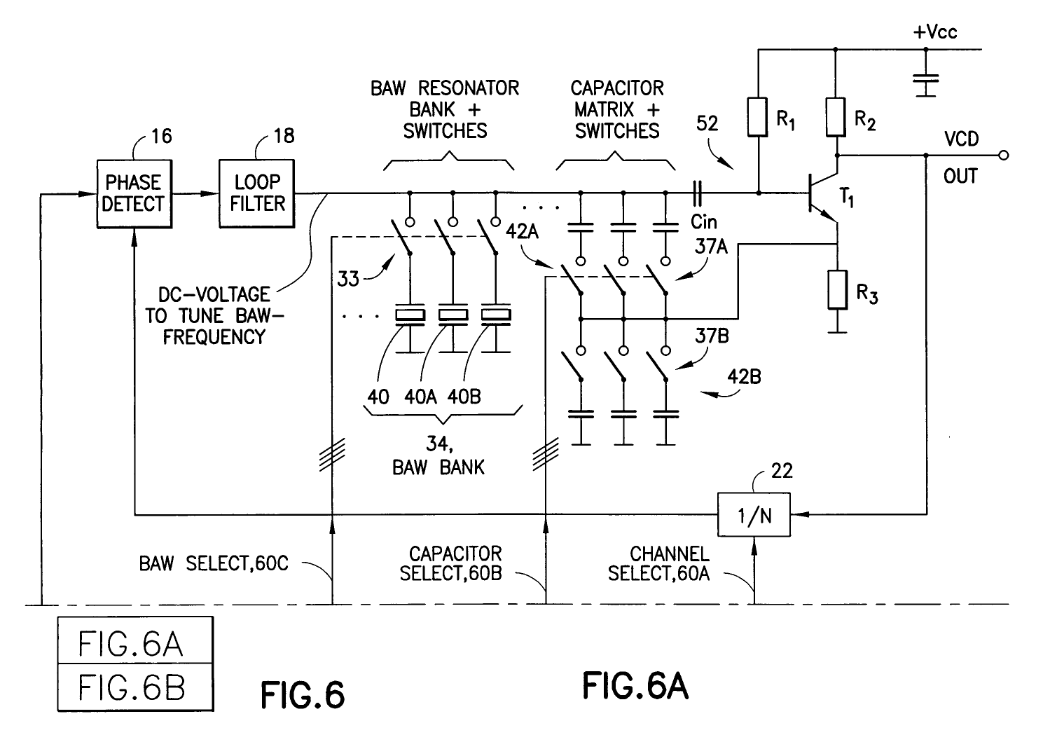

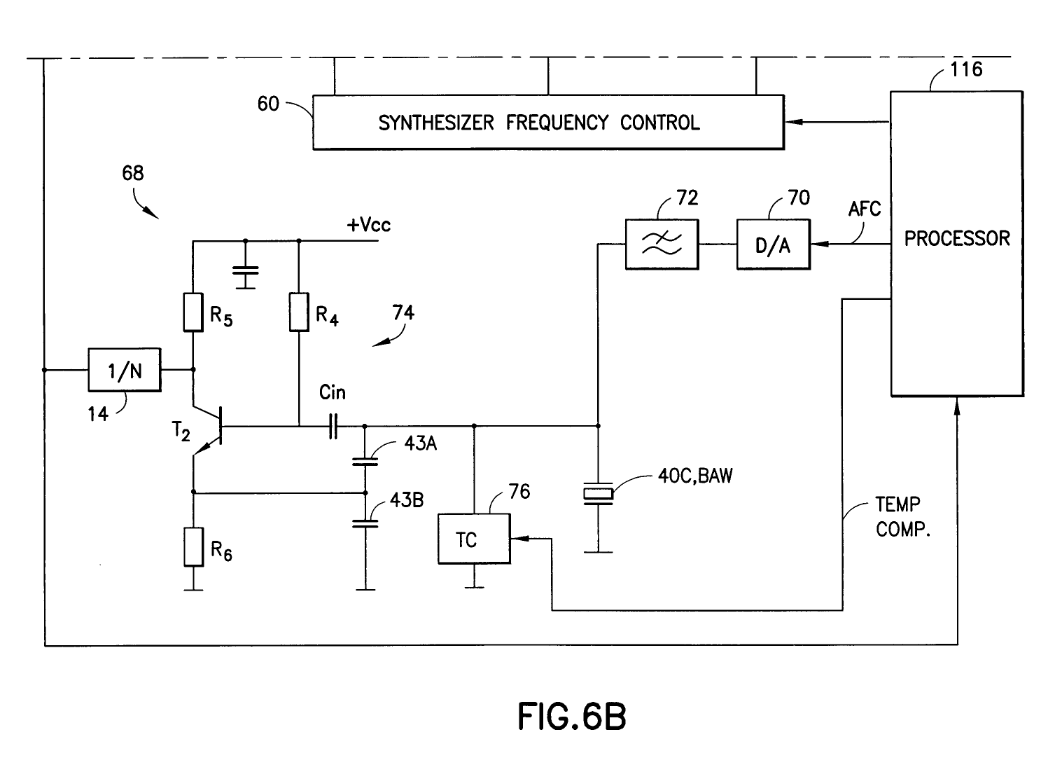

Referring to FIG. 6, in a further embodiment of this invention a further BAW resonator 40C is used as part of a reference oscillator 68 that replaces the crystal-based reference oscillator 12 shown in FIG. 3. The reference oscillator 68 provides the master reference frequency for the PLL 50 of the frequency synthesizer 114. The BAW resonator 40C is preferably accurately tuned and temperature compensated so that mobile station 100 can be tuned to receive the base station frequency reference signal before locking to that reference. If the reference oscillator is inaccurate, then the received signal may be attenuated and fall outside of the bandwidth of the received channel.

As one example, in order to communicate with the DCS 1800 radiotelephone system, a DCS 1800 radiotelephone performs automatic frequency control (AFC) to synchronize the receiver of the radiotelephone to the base station transmitter of the system. AFC includes automatically correcting, to within an acceptable degree of error, any frequency errors between the carrier frequency of the signal received from the base station transmitter and the frequency of a reference oscillator of the radiotelephone from which receiver reception is set. The DCS 1800 radiotelephone initiates AFC by receiving and processing a 67 kHz tone sent by a DCS 1800 base station transmitter on a control channel. The processed 67 kHz tone is used to control the reference oscillator frequency of the DCS 1800 radiotelephone. Typically, the radiotelephone reference oscillator frequency stability over temperature is less than 1 ppm/° C., whereas BAW resonators are typically not as stable. However, crystal oscillators are expensive components, and cannot at present be integrated within an integrated circuit.

Methods to tune wafer-level BAW resonators in production are known in the art. For example, reference can be made to the following commonly assigned U.S. patents and Published patent applications: U.S. Pat. No. 6,441,702. “Method and System for Wafer-Level Tuning of Bulk Acoustic Wave Resonators and Filters”; U.S. Pat. No. 6,456,173, “Method and System for Wafer-Level Tuning of Bulk Acoustic Wave Resonators and Filters”, U.S. 20020158714 A1, Method and System for Wafer-Level Tuning of Bulk Acoustic Wave Resonators and Filters by Reducing Thickness Non-Uniformity”, and U.S. 20020158702 A1, “Method and System for Wafer-Level Tuning of Bulk Acoustic Wave Resonators and Filters”, incorporated by reference herein in their entireties.

In FIG. 6 the reference oscillator 68 includes an active transistor circuit 74 containing transistor T2 and associated resistances R4, R5, R6 and capacitors Cin, 43A and 43B.The BAW resonator 40C is connected at the input of the transistor circuit 74. A capacitor matrix for coarse tuning is not required, as it is assumed that the BAW resonator 40C is pre-tuned during the manufacturing process, and the required tuning range is narrow. An AFC synchronizing signal received from base station, or otherwise derived, is processed and converted to a DC signal (AFC) indicative of the frequency error by a digital-to-analog converter (DAC) 70. The AFC signal is filtered at block 72 and input to the reference oscillator BAW resonator 40C electrode 41A to fine tune the reference oscillator frequency, and lock it to the frequency received from the base station. The oscillator circuit 74 is followed by the divider 14 to divide output frequency to one appropriate for the phase detector 16. The same output signal can be fed for reference or clock signal purposes to other stages of the mobile station 100, such as the processor 116 and data converters.

It is preferred that a temperature compensation signal be applied to a temperature compensation block 76 for correcting the BAW resonator output frequency for changes in operating temperature. Various methods to temperature compensate mobile station reference oscillators are known in the art, as evidenced by the commonly assigned U.S. Pat. No. 5,649,320, “Automatic Frequency Control Loop and Temperature Compensation for a Receiver”, incorporated by reference herein.

The frequency of the BAW reference oscillator 74, before divider 14, may be near the VCO frequency, for example about 900 MHz.

While FIG. 6 shows the use of the VCO BAW resonator(s) 40, 40A, 40B, as well as the reference oscillator BAW resonator 40C, it should be appreciated that in some embodiments of this invention only the reference oscillator BAW resonator 40C can be used, while the VCO 20 is constructed in a conventional (non-BAW resonator) manner.

It should be further appreciated that the use of the embodiment of FIG. 6 enables the reference oscillator 68 to also be integrated onto the same substrate as the PLL and VCO, thereby achieving even further savings in cost and required circuit area.

In some embodiments, wherein the VCO 20 is constructed in a conventional (non-BAW resonator) manner, wafer-level BAW resonator tuning methods can be replaced with software tuning. In such an embodiment there is only one BAW resonator 40 integrated on the same substrate as the PLL 50, and implementing capacitor array tuning may be more cost effective than wafer-level tuning. In such an embodiment the reference oscillator 68 capacitors 43A and 43B can be replaced with a switched capacitor array similar to the array 42A and 42B used in the VCO oscillator 52, and coarse tuning of the reference oscillator 68 can be accomplished as discussed above with regard to the VCO tuning procedure. In this case the BAW resonator 40C is manufactured to have its resonant frequency greater than the desired final frequency, the resonant frequency is coarse tuned down with the capacitor array, and is fine tuned with the AFC signal to lock the reference frequency signal to the base station reference frequency.

The foregoing description has provided by way of exemplary and non-limiting examples a full and informative description of the best method and apparatus presently contemplated by the inventor for carrying out the invention. However, various modifications and adaptations may become apparent to those skilled in the relevant arts in view of the foregoing description, when read in conjunction with the accompanying drawings and the appended claims. As but some examples, the use of other numbers of acoustic resonators, capacitance networks, switches and the like can all be attempted by those skilled in the art. Furthermore, other mobile device architectures than that specifically shown in FIG. 4, such as superheterodyne architectures, can be employed. However, all such and similar modifications of the teachings of this invention will still fall within the scope of this invention. Further, while the method and apparatus described herein are provided with a certain degree of specificity, the present invention could be implemented with either greater or lesser specificity, depending on the needs of the user. Further, some of the features of the present invention could be used to advantage without the corresponding use of other features. As such, the foregoing description should be considered as merely illustrative of the principles of the present invention, and not in limitation thereof, as this invention is defined by the claims which follow.

What is claimed is:

1. A frequency synthesizer, comprising:
a reference oscillator;
a phase comparator having a first input coupled to an output of said reference oscillator and outputting a frequency tuning voltage;
a VCO having an input coupled to the frequency tuning voltage and outputting an output frequency signal;
a programmable divider coupled to the output frequency signal and providing a divided output frequency signal to a second input of said phase comparator; where
said VCO comprises at least one acoustic resonator coupled to said frequency tuning voltage.

2. A frequency synthesizer as in claim 1, where at least said phase comparator, said VCO, including said at least one acoustic resonator, and said programmable divider are all integrated on a single integrated circuit substrate.

3. A frequency synthesizer as in claim 1, where said frequency synthesizer forms a part of a wireless communication device.

4. A frequency synthesizer as in claim 1, where said frequency synthesizer forms a part of a cellular telephone.

5. A frequency synthesizer as in claim 1, where said reference oscillator comprises at least one acoustic resonator.

6. A frequency synthesizer as in claim 1, where said reference oscillator comprises at least one acoustic resonator coupled to an automatic frequency control tuning voltage.

7. A frequency synthesizer, comprising:
a reference oscillator;
a phase comparator having a first input coupled to an output of said reference oscillator and outputting a frequency tuning voltage;
a VCO having an input coupled to the frequency tuning voltage and outputting an output frequency signal;
a programmable divider coupled to the output frequency signal and providing a divided output frequency signal to a second input of said phase comparator; where
said VCO comprises at least one acoustic resonator coupled to said frequency tuning voltage, and further comprises a plurality of capacitances that are switchably coupled in parallel with said at least one acoustic resonator for extending a tuning range of said VCO.

8. A frequency synthesizer as in claim 7, where at least said phase comparator, said VCO, including said at least one acoustic resonator and said plurality of capacitors, and said programmable divider are all integrated on a single integrated circuit substrate.

9. A frequency synthesizer as in claim 7, where said frequency synthesizer forms a part of a wireless communication device.

10. A frequency synthesizer as in claim 7, where said frequency synthesizer forms a part of a cellular telephone.

11. A frequency synthesizer as in claim 7, where said reference oscillator comprises at least one acoustic resonator.

12. A frequency synthesizer as in claim 7, where said reference oscillator comprises at least one acoustic resonator coupled to an automatic frequency control tuning voltage.

13. A frequency synthesizer, comprising:
a reference oscillator;
a phase comparator having a first input coupled to an output of said reference oscillator and outputting a frequency tuning voltage;
a VCO having an input coupled to the frequency tuning voltage and outputting an output frequency signal;
a programmable divider coupled to the output frequency signal and providing a divided output frequency signal to a second input of said phase comparator; where
said VCO comprises a plurality of acoustic resonators that are switchably coupled to said frequency tuning voltage for extending a tuning range of said VCO.

14. A frequency synthesizer as in claim 13, where at least said phase comparator, said VCO, including said plurality of acoustic resonators, and said programmable divider are all integrated on a single integrated circuit substrate.

15. A frequency synthesizer as in claim 13, where said frequency synthesizer forms a part of a wireless communication device.

16. A frequency synthesizer as in claim 13, where said frequency synthesizer forms apart of a cellular telephone.

17. A frequency synthesizer as in claim 13, where said reference oscillator comprises at least one acoustic resonator.

18. A frequency synthesizer as in claim 13, where said reference oscillator comprises at least one acoustic resonator coupled to an automatic frequency control tuning voltage.

19. A frequency synthesizer, comprising:
a reference oscillator;
a phase comparator having a first input coupled to an output of said reference oscillator and outputting a frequency tuning voltage;
a VCO having an input coupled to the frequency tuning voltage and outputting an output frequency signal;
a programmable divider coupled to the output frequency signal and providing a divided output frequency signal to a second input of said phase comparator; where
said VCO comprises a plurality of acoustic resonators that are switchably coupled to said frequency tuning voltage, and further comprises a plurality of capacitances that are switchably coupled in parallel with said plurality of acoustic resonators, all for extending a tuning range of said VCO.

20. A frequency synthesizer as in claim 19, where at least said phase comparator, said VCO, including said plurality of acoustic resonators and said plurality of capacitances, and said programmable divider are all integrated on a single integrated circuit substrate.

21. A frequency synthesizer as in claim 19, where said frequency synthesizer forms a part of a wireless communication device.

22. A frequency synthesizer as in claim 19, where said frequency synthesizer forms a part of a cellular telephone.

23. A frequency synthesizer as in claim 19, where said reference oscillator comprises at least one acoustic resonator.

24. A frequency synthesizer as in claim 19, where said reference oscillator comprises at least one acoustic resonator coupled to an automatic frequency control tuning voltage.

25. A wireless communication device, comprising:
an RF transceiver for operating in at least one band of frequencies; and
a frequency synthesizer comprising a PLL that includes a VCO;
said VCO comprising, for operation in said at least one band of frequencies, a bank of tunable acoustic resonators that are individually switchably coupled to a frequency tuning voltage of said PLL.

26. A wireless communication device as in claim 25, where said bank of tunable acoustic resonators are further switchably coupled to individual capacitors of a multi-capacitor matrix for varying a resonant frequency of a selected on of the BAW resonators.

27. A wireless communication device as in claim 25, where said individual capacitors of said multi-capacitor matrix have capacitance values that are binarily weighted one to another.

28. A wireless communication device as in claim 25 and further comprising, for operation in a second band of frequencies, a second bank of tunable acoustic resonators that are switchably coupled to said frequency tuning voltage of said PLL.

29. A wireless communication device as in claim 25, where individual acoustic resonators of said bank of tunable acoustic resonators are tunable within a range of frequencies that overlaps a range of frequencies of at least one other acoustic resonator.

30. A wireless communication device as in claim 25, where said PLL comprises a phase detector having an input coupled to an output of a reference oscillator, where said reference oscillator comprises at least one acoustic resonator.

31. A wireless communication device as in claim 25, where said PLL comprises a phase detector having an input coupled to an output of a reference oscillator, where said reference oscillator comprises at least one acoustic resonator coupled to an automatic frequency control tuning voltage.

32. A method of operating a frequency synthesizer, comprising:
in response to a command to set an output frequency value, selecting an acoustic resonator from a bank of acoustic resonators that comprise a part of a phase locked loop (PLL), the selected acoustic resonator having a characteristic resonant frequency that is tunable within a range that includes the output frequency value;
coupling at least one capacitor from a bank of capacitors to the selected acoustic resonator for coarsely tuning the resonant frequency of the selected acoustic resonator to be approximately equal to the output frequency value;
selecting a divisor for the frequency synthesizer output frequency, that corresponds to a desired PLL output frequency, to generate a divided frequency signal;
responsive to a reference frequency and the divided frequency signal, generating a DC voltage with a PLL phase comparator;
filtering the DC voltage with a PLL loop filter to generate a filtered DC voltage; and
applying the filtered DC voltage to the selected acoustic resonator for fine tuning the resonant frequency of the selected acoustic resonator to be substantially equal to the output frequency value.

33. A method as in claim 32, further comprising applying an automatic frequency control signal to a further BAW resonator that forms part of a reference oscillator circuit outputting a reference frequency to the PLL.

34. A frequency synthesizer, comprising:
means, responsive to a command to set an output frequency value, for selecting an acoustic resonator from a bank of acoustic resonators that comprise a part of a phase locked loop (PLL), said selected acoustic resonator having a characteristic resonant frequency that is tunable within a range that includes the output frequency value;
means for coupling at least one capacitor from a bank of capacitors to the selected acoustic resonator for coarsely tuning the resonant frequency of the selected acoustic resonator to be approximately equal to the output frequency value;
means for generating a divided frequency signal;
means, responsive to a reference frequency and the divided frequency signal, for generating a DC voltage indicative of a difference between the reference frequency and the divided frequency signal;
means for filtering the DC voltage to generate a filtered DC voltage; and
means for applying the filtered DC voltage to the selected acoustic resonator for fine tuning the resonant frequency of the selected acoustic resonator to be substantially equal to the output frequency value.

35. A frequency synthesizer as in claim 34, where said PLL comprises a phase detector having an input coupled to an output of a reference oscillator, where said reference oscillator comprises at least one acoustic resonator.

36. A wireless communication device, comprising:
an RF transceiver for operating in at least one band of frequencies; and
a frequency synthesizer comprising a PLL that includes a VCO;
said PLL comprising a phase detector having an input coupled to an output of a reference oscillator, where said reference oscillator comprises at least one acoustic resonator coupled to an automatic frequency control tuning voltage.

37. A wireless communication device as in claim 36, where said VCO comprises, for operation in said at least one band of frequencies, at least one further acoustic resonator coupled to a frequency tuning voltage of said PLL.

38. A wireless communication device as in claim 36, where said VCO comprises, for operation in said at least one band of frequencies, a bank of tunable acoustic resonators that are individually switchably coupled to a frequency tuning voltage of said PLL.

39. A wireless communication device as in claim 38, where said bank of tunable acoustic resonators are further switchably coupled to individual capacitors of a multi-capacitor matrix for varying a resonant frequency of a selected on of the BAW resonators.

40. A wireless communication device as in claim 39, where said individual capacitors of said multi-capacitor matrix have capacitance values that are binarily weighted one to another.

41. A wireless communication device as in claim 38 and further comprising, for operation in a second band of frequencies, a second bank of tunable acoustic resonators that are switchably coupled to said frequency tuning voltage of said PLL.

42. A wireless communication device as in claim 41, where individual acoustic resonators of said bank of tunable acoustic resonators are tunable within a range of frequencies that overlaps a range of frequencies of at least one other acoustic resonator.

43. A frequency synthesizer, comprising:
a reference oscillator comprising at least one first acoustic resonator;
a phase comparator having a first input coupled to an output of said reference oscillator and outputting a frequency tuning voltage;
a VCO having an input coupled to the frequency tuning voltage and outputting an output frequency signal, said VCO comprising at least one second acoustic resonator coupled to said frequency tuning voltage; and
a programmable divider coupled to the output frequency signal and providing a divided output frequency signal to a second input of said phase comparator; where
at least said reference oscillator, including said at least one first acoustic resonator, said phase comparator, said VCO, including said at least one second acoustic resonator, and said programmable divider are all integrated on a single integrated circuit substrate.

44. A reference frequency oscillator for use in a wireless communication device, comprising an acoustic resonator having an input coupled to an automatic frequency control tuning voltage, said acoustic resonator being switchably coupled to individual ones of a plurality of capacitances for varying a resonant frequency of said acoustic resonator, where at least one of said plurality of capacitances is switchably selected for coarse tuning said oscillator to a desired frequency, and where said automatic frequency control tuning voltage is varied for fine tuning said oscillator.
